(19) United States
(12) Patent Application Publication
(10) Pub. No.: US 2007/0041484 A1
(43) Pub. Date: Feb. 22, 2007

(54) Method and system for a digital frequency divider

(76) Inventor: Karapet Khanoyan, Lake Forest, CA (US)

Correspondence Address: MCANDREWS HELD & MALLOY, LTD, 500 WEST MADISON STREET, SUITE 3400, CHICAGO, IL, 60661, US

(21) Appl. No.: 11/207,207

(22) Filed: Aug. 16, 2005

(51) Int. Cl. H03D 3/24

(52) U.S. Cl. 375/376

(57) ABSTRACT

Methods and systems for generating a signal are disclosed herein and may comprise digitally frequency dividing a input signal by a factor value specified as an N+1-bit value, utilizing a counter of N bits. A count value may be generated based on a number of cycles of the input signal and a generated count value compared with the factor value to generate a match signal comprising a pipelined match signal. The comparison may be performed utilizing a pipelined count value. An output signal from the digitally frequency dividing may be toggled utilizing the match signal. The digital frequency dividing may be performed utilizing a single comparator and may be performed utilizing a single counter. One of two clock signals may be selected and utilized to toggle the output signal. One bit of the factor value, and the output signal, may be utilized to select one of two clock signals.

### RELATED APPLICATIONS

This application makes reference to U.S. patent application Ser. No. ______ (Attorney Docket Number 16648US01) filed Aug. 16, 2005.

The above stated application is hereby incorporated herein by reference in its entirety.

### FEDERALLY SPONSORED RESEARCH OR DEVELOPMENT

Not Applicable

### MICROFICHE/COPYRIGHT REFERENCE

Not Applicable

### FIELD OF THE INVENTION

Certain embodiments of the invention relate to generating electrical signals. More specifically, certain embodiments of the invention relate to a method and system for a digital frequency divider.

### BACKGROUND OF THE INVENTION

High-speed digital communication networks over copper and optical fiber are used in many network communication and digital storage applications. Ethernet and Fiber Channel are two widely used communication protocols, which continue to evolve in response to increasing demands for higher bandwidth in digital communication systems. The Ethernet protocol may provide collision detection and carrier sensing in the physical layer of the OSI reference model. The physical layer, layer 1, is responsible for handling all electrical, optical, opto-electrical and mechanical requirements for interfacing to the communication media. Notably, the physical layer may facilitate the transfer of electrical signals representing an information bitstream. The physical layer (PHY) may also provide services such as, encoding, decoding, synchronization, clock data recovery, and transmission and reception of bit streams. Some PHY services may be provided by one or more Ethernet PHY transceivers.

As the demand for higher data rates and bandwidth continues to increase, equipment vendors are continuously being forced to employ new design techniques for manufacturing network equipment capable of handling these increased data rates. In response to this demand, physical layer (PHY) transceivers have been designed to operate at gigabit speeds to keep pace with this demand for higher data rates. Gigabit Ethernet, which initially found application in gigabit servers, is becoming widespread in personal computers, laptops, and switches, thereby providing the necessary infrastructure for handling data traffic of PCs and packetized telephones. At gigabit speeds, generation of clocks of different frequencies for use by the gigabit Ethernet transceiver is central to the operation of the transceiver. This is particularly true for phase locked loop circuits implemented in the transceiver. In this regard, gigabit Ethernet transceivers may be adapted to utilize one or more digital frequency dividers for the creation of one or more clocks within the integrated circuit. A digital frequency divider may be utilized to accept a high-frequency input clock signal and generate a lower-frequency clock whose frequency is an integer factor of the input clock.

Conventional digital frequency dividers, however, may utilize multiple comparators, increasing the capacitive loading on the counter circuit in the circuit's critical signal path. Conventional digital frequency dividers may utilize N-bit counters to achieve a digital frequency division factor of 2ΛN, increasing the complexity associated with adding the N-th bit to the counter circuit in the circuit critical path. Conventional digital frequency dividers may not pipeline signals along the critical signal path, or the longest signal timing path within the digital frequency divider. These features of conventional digital frequency dividers may significantly decrease the maximum input clock frequency that the digital frequency divider can utilize.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A system and/or method for a digital frequency divider, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of an exemplary integrated circuit system with a phase locked loop, which may be utilized in accordance with an embodiment of the invention.

FIG. 2A is a block diagram of an exemplary digital frequency divider, in accordance with an embodiment of the invention.

FIG. 2B is a block diagram of an exemplary digital frequency divider control block, which may be utilized in accordance with an embodiment of the invention.

FIG. 3 is a block diagram of an exemplary single counter of FIG. 2A, which may be utilized in accordance with an embodiment of the invention.

FIG. 4A is a block diagram of an exemplary digital frequency divider comparator block of FIG. 2A, which may be utilized in accordance with an embodiment of the invention.

FIG. 4B is a block diagram of the exemplary comparator block of FIG. 2A, which may be utilized in accordance with another embodiment of the invention.

FIG. 5 is a block diagram of the exemplary counter reset and divider output block, which may be utilized in accordance with an embodiment of the invention.

FIG. 6 is a flow diagram of exemplary steps for digitally generating frequency divided output signals, in accordance with an embodiment of the invention.

### DETAILED DESCRIPTION OF THE INVENTION

Certain embodiments of the invention may be found in a method and system for a digital frequency divider. In one aspect of the invention, a digital frequency divider may be implemented with fewer comparator blocks than other digital frequency dividers and operates at higher clock frequencies. In another aspect of the invention, the digital frequency divider may double the frequency programmability range of other digital frequency dividers without having to increase a counter size by an additional bit. The digital frequency divider disclosed herein may also utilize various registers to pipeline signals and interrupt critical timing paths. A digital frequency divider implemented according to an embodiment of the invention may contribute to a reduction in the silicon area required to implement an integrated circuit or chip. For example, the digital frequency divider may utilize a reduced number of integrated circuit (IC) components such as gates compared to other frequency dividers. The reduced number of IC components results such as the gates and comparator blocks results in reduced power consumption when compared to other frequency dividers.

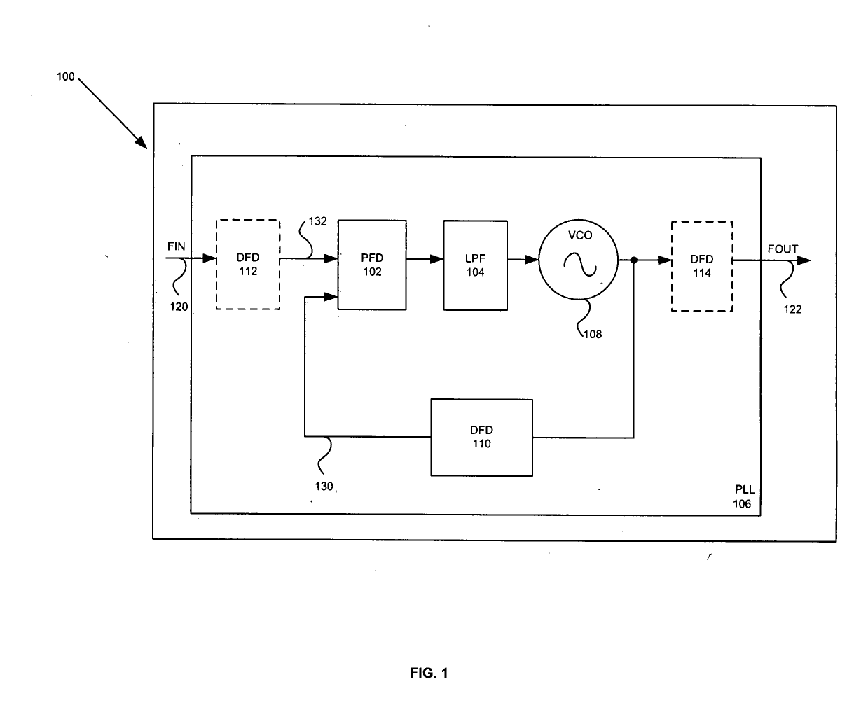

FIG. 1 is a block diagram of an exemplary integrated circuit system with a phase locked loop, which may be utilized in accordance with an embodiment of the invention. Referring to FIG. 1, the exemplary integrated circuit (IC) system 100 may comprise a phase locked loop 106. The phase locked loop 106 may comprise phase frequency detect (PFD) block 102, loop filter (LPF) block 104, VCO block 108, and digital frequency dividers (DFD) 110, 112, and 114. An output of digital frequency divider (DFD) 112 may be coupled to an input of the PFD 102 and an output of the PFD 102 may be coupled to an input of the LPF 104. An output of the LPF 104 may be coupled to an input of the VCO 108 and an output of the VCO 108 may be coupled to an input of the digital frequency divider (DFD) 114 and an input of the digital frequency divider (DFD) 110. An output of digital frequency divider (DFD) 110 may also be coupled to an input of the PFD 102.

The phase frequency detect (PFD) block 102 may comprise suitable logic and/or circuitry that may be adapted to compare the frequencies of two periodic input signals, and generate an output that reflects the phase and/or frequency difference between the two input signals.

The loop filter block (LPF) 104 may comprise suitable logic and/or circuitry that may be adapted to filter and amplify an input signal and generate a voltage signal suitable for use by a voltage controlled oscillator.

The voltage control oscillator (VCO) block 108 may comprise suitable logic and/or circuitry that may be adapted to accept a voltage input and produce a periodic output signal.

The digital frequency dividers (DFD) 110, 112, and 114 may comprise suitable logic and/or circuitry that may be adapted to accept a periodic input signal and produce an output whose frequency is a factor of the input signal frequency.

In operation, the PLL block 106 within the IC 100 may generate a periodic output clock (FOUT) 122 which may be coupled to inputs of other logic in the integrated circuit (IC) 100 or may be an output of the integrated circuit (IC) 100. The input signal FIN 120 received by the PLL block 106 may be divided in frequency by the digital frequency divider (DFD) block 112 to generate a divided input signal 132. The phase frequency detect (PFD) block 102 may compare the frequency and phase of the divided input signal 132 with the output of the digital frequency divider (DFD) block 110, and may produce an output signal which is a result of the comparison. The output of the phase frequency detect (PFD) block 102 may be filtered and amplified by the loop filter (LPF) 104, to produce a voltage output that may be used by voltage controlled oscillator (VCO) block 108 to produce a periodic output.

The output of voltage controlled oscillator (VCO) block 108 may be divided in frequency by the digital frequency divider (DFD) block 110 to produce the divided VCO output 130, and fed back to the phase frequency detect (PFD) block 102. In operation, the filtered output of the phase frequency detect (PFD) block 102 may adjust the output of the voltage controlled oscillator (VCO) block 108 to eliminate any phase and/or frequency differences that may exist between the divided VCO output 130 and the divided input 132. When the differences in the phase and/or the frequency occur, the PLL 106 may be said to be in a “locked” condition. The output of the voltage controlled oscillator (VCO) block 108 may be divided in frequency by the digital frequency divider (DFD) block 114 to produce a periodic output clock (FOUT) 122. The periodic output clock (FOUT) 122 may be the output of the PLL block 106, and that may be coupled to inputs of other logic in the integrated circuit (IC) 100 or may be an output of the integrated circuit (IC) 100. The digital frequency divider (DFD) blocks 110, 112, 114 may be used to adjust the frequency relationship between the PLL input FIN 120 and the PLL output FOUT 122.

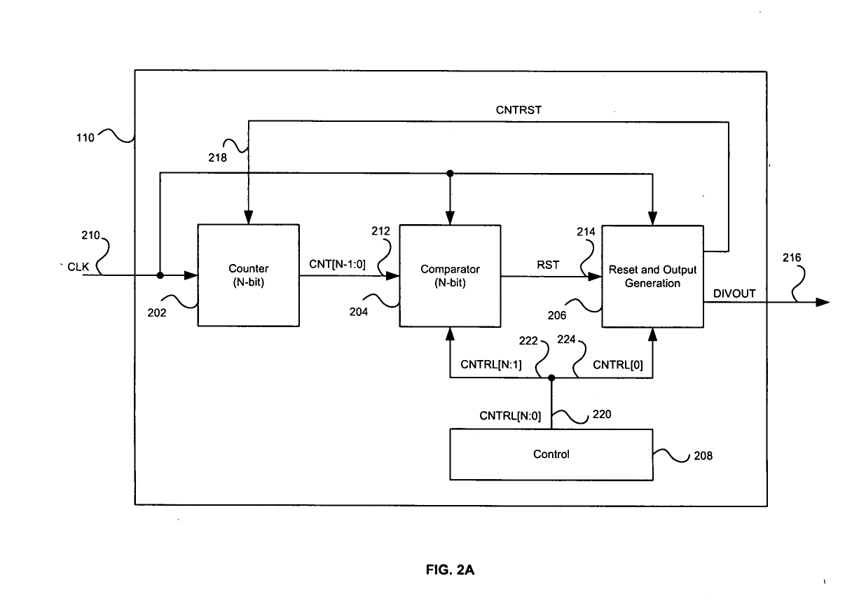

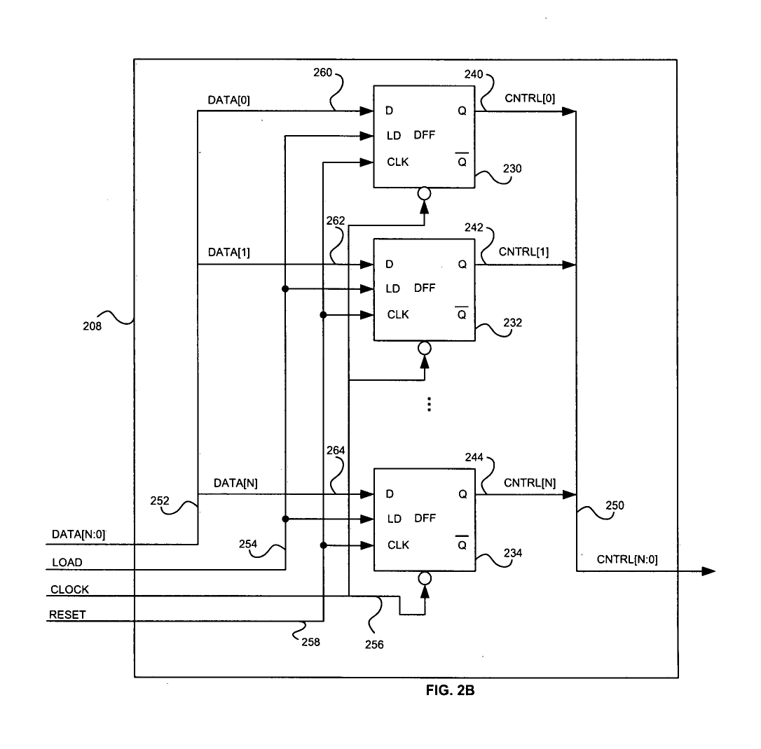

FIG. 2A is a block diagram of an exemplary digital frequency divider 110 of FIG. 1, in accordance with an embodiment of the invention. Referring to FIG. 2A, the exemplary digital frequency divider 110 may comprise a control block 208, a single counter 202, a comparator block 204, and a counter reset and output generation block 206. The control block 208 may be coupled to an input of the comparator block 204 and the counter reset and output generation block 206. An output of the single counter 202 may be coupled to an input of the comparator block 204 and an output of the comparator block 204 may be coupled to an input of the counter reset and output generation block 206. An input clock signal (CLK) 210 is coupled to the single counter 202, the comparator block 204, and the counter reset and output generation block 206. An output of the counter reset and output generation block 206 may be coupled to an input of the single counter 202. A frequency divided output signal (DIVOUT) 216 may be coupled to the counter reset and output generation block 206.

The control block 208 may comprise suitable logic and/or circuitry that may be adapted to store a plurality of control or configuration values, that may be presented on the output control bus (CNTRL[N:0]) 220. In one embodiment of the invention, the control block 208 may store (N+1) bits of control or configuration values. Further details of the control block 208 are illustrated in FIG. 2B. In an embodiment of the invention, the control block 208 may comprise suitable circuitry, logic, and/or code and may be adapted to store a plurality of control or configuration values, which may be presented on an output control bus. The configuration values may be updated using an input data bus when a load signal is asserted for at least one cycle of the clock 256, and the reset 256 is de-asserted.

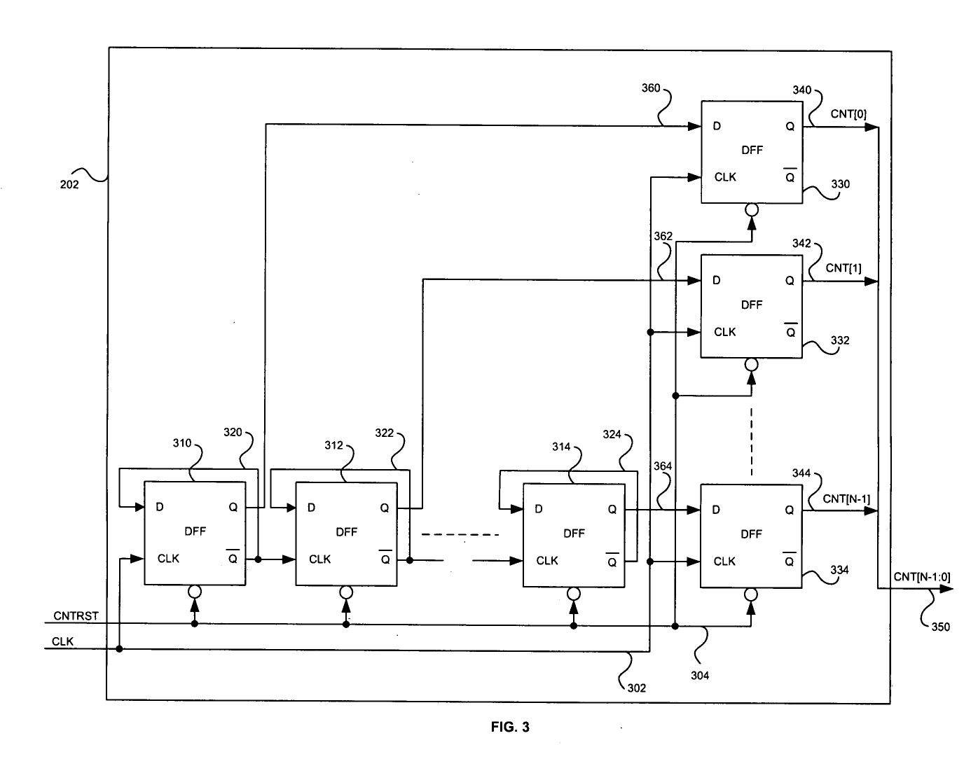

The single counter 202 may comprise suitable logic and/or circuitry that may be adapted to receive a clock (CLK) 210 and counter reset (CNTRST) 218 inputs, and for each cycle of the clock (CLK) 210 where the counter reset (CNTRST) 218 is de-asserted, increment an N-bit count value presented on the counter output CNT[N−1:0] 212, and when the counter reset (CNTRST) 218 is asserted, present a determined reset value on the counter output CNT[N−1:0] 212. Further details of the single counter 202 are illustrated in FIG. 3. In one embodiment of the invention, the single counter 202 may be an N-bit counter. The single counter 202 may be adapted to receive an input clock signal (CLK) 210 and generate an output count signal CNT[N−1:0] 212.

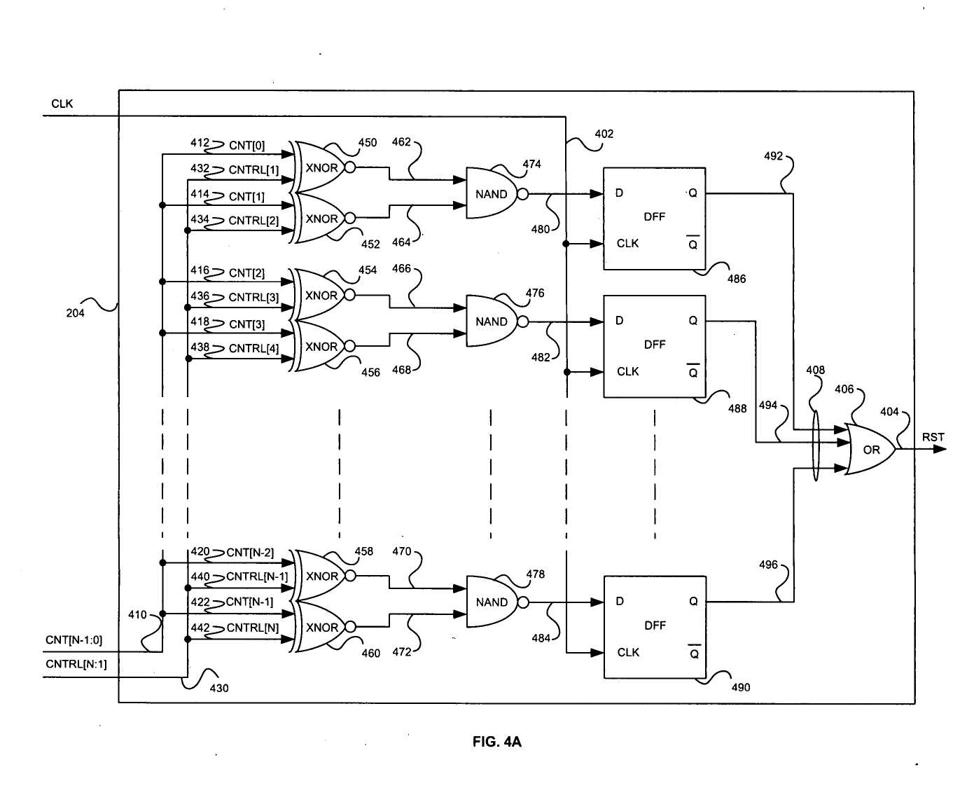

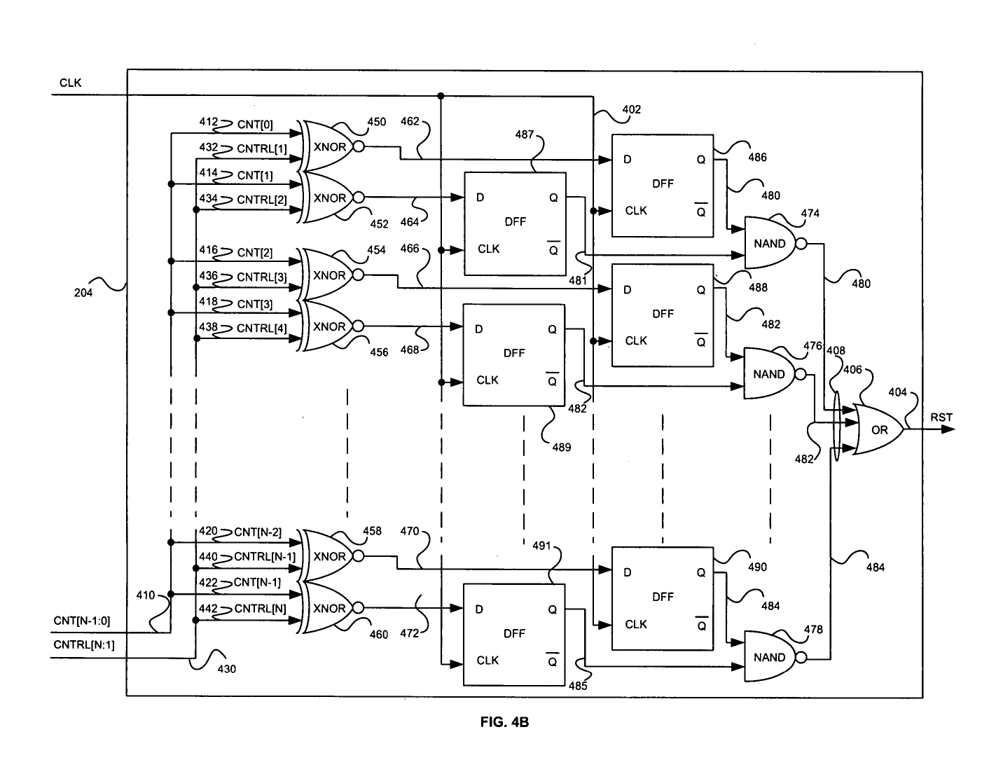

The comparator block 204 may comprise suitable logic and/or circuitry that may be adapted to compare an N-bit count value (CNT[N−1:0]) 212 with an N-bit control value (CNTRL[N:1]) 222, and assert an output comparison result signal (RST) 214, that may be delayed by one or more cycles of the clock 210, when the N-bit count value (CNT[N−1:0]) 212 and the N-bit control value (CNTRL[N:1]) 222 are identical. Further details of the comparator block 204 are illustrated in FIG. 4A. In an embodiment of the invention, the comparator block 204 may compare two N-bit values, and assert a comparison result output if the values are identical. The comparator block 204 may be adapted to receive a count signal CNT[N−1:0] generated by the single counter 202 and generate an output reset signal (RST) 214. The comparator block 204 may also be adapted to receive as an input a control signal CNTRL[N:1], which is generated by the control block 208. The clock signal (CLK) 210 may also be provided as an input to the comparator block 204.

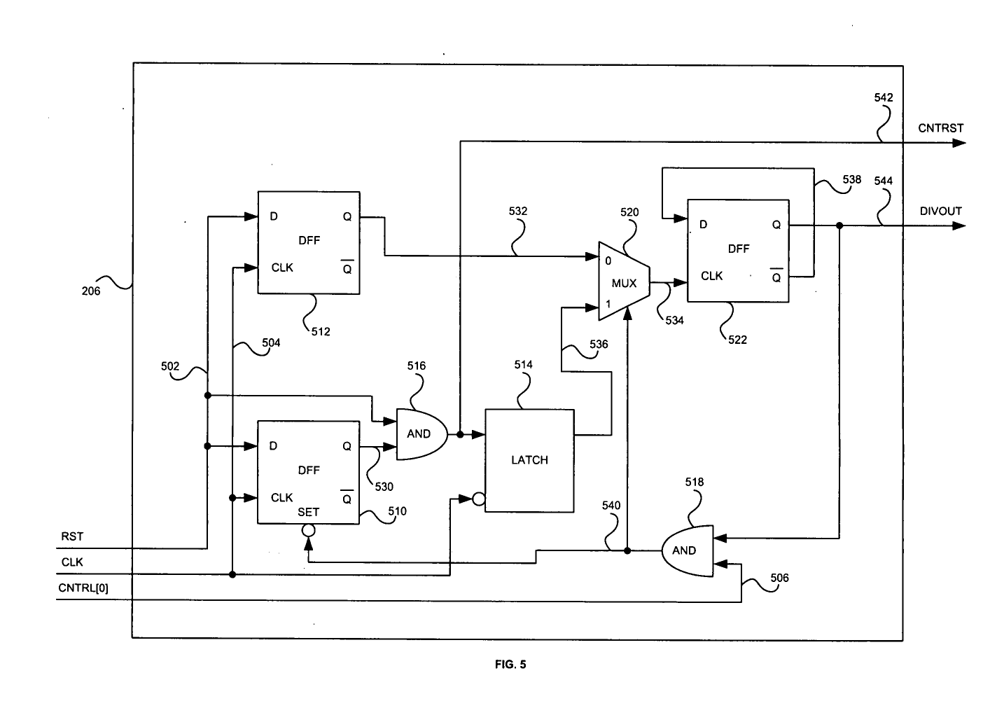

The counter reset and output generation block 206 may comprise suitable logic and/or circuitry that may be adapted to generate a counter reset signal CNTRST 218. Further details of the counter reset and output generation block 206 are illustrated in FIG. 5. The counter reset signal CNTRST 218 may be utilized to reset the single counter 202. The counter reset and output generation block 206 may also be adapted to receive as an input the reset signal RST 214, which is generated as an output of the comparator block 204. The counter reset and output generation block 206 may be adapted to reset the single counter 202. The clock signal (CLK) 210 may also be provided as an input to the comparator block 204. The counter reset and output generation block 206 may generate a frequency divided output signal (DIVOUT) 216.

The output control bus (CNTRL[N:0]) 220 of the control block 208 may be used to control the operation of the comparator block 204. The comparator block 204 may accept N-bits of the output control bus (CNTRL[N:0]) 220. The comparator block 204 may compare the N-bit control input (CTRL[N:1]) 222 with the N-bit input from the single counter 202, and may assert an output comparison result signal (RST) 214 if the two N-bit inputs 220 and 222 are identical. When a different value of N-bit control input (CTRL[N:1]) 222 is used, comparator block 204 asserts output comparison result signal (RST) 214 at a corresponding different value of the N-bit count value (CNT[N−1:0]) 212. In an embodiment of the invention, the N-bit control input (CTRL[N:1]) 222 is generated utilizing bits [N:1] of output control bus (CNTRL[N:0]).

The output control bus (CNTRL[N:0]) 220 of the control block 208 may be used to control the operation of the counter reset and output generation block 206. When the control input (CTRL[0]) 224 de-asserted, the counter reset and output generation block 206 may generate a frequency divided output signal (DIVOUT) 216 that is an even frequency division of the input clock signal (CLK) 210. When the control input (CTRL[0]) 224 is asserted, the counter reset and output generation block 206 may generate a frequency divided output signal (DIVOUT) 216 that is an odd frequency division of the input clock signal (CLK) 210. In an embodiment of the invention, the control input (CTRL[0]) 224 is generated utilizing bit [0] of the output control bus (CNTRL[N:0]).

In operation, the digital frequency divider block 110 receives an input clock signal (CLK) 210, and the count value (CNT[N−1:0]) 212 stored in the single counter 202 may increment once per cycle of the input clock signal (CLK) 210 when the counter reset (CNTRST) 218 is de-asserted. The comparator block 204 may assert an output comparison result signal (RST) 214 when the count value (CNT[N−1:0]) 212 is identical to the determined N-bit control value (CNTRL[N:1]) 222. The reset and output generation block may detect the assertion of the output comparison result signal (RST) 214 and may assert the counter reset (CNTRST) 218 output. The reset and output generation block may detect the assertion of the output comparison result signal (RST) 214 and may toggle the frequency divided output signal (DIVOUT) 216. The single counter 202 may reset to a determined value when the counter reset (CNTRST) 218 input is asserted, and may resume counting, incrementing the count value (CNT[N−1:0]) 212 once per cycle of input clock signal (CLK) 210, when the counter reset (CNTRST) 218 input is de-asserted.

FIG. 2B is a block diagram of an exemplary digital frequency divider control block 208 of FIG. 2A, which may be utilized in accordance with an embodiment of the invention. Referring to FIG. 2B, the control block 208 may comprise flip-flops 230, 232, . . . , 234. An input clock signal (CLOCK) 256 may be coupled to the flip-flops 230, 232, . . . , 234. A load enable signal (LOAD) 254 may be coupled to the flip-flops 230, 232, . . . , 234. A reset signal (RESET) 258 may be coupled to the flip-flops 230, 232, . . . , 234. The data bit signals, 260, 262, . . . 264 may be coupled to bit 0, 1, . . . , N of the (N+1) bit input data bus (DATA[N:0]) 252. The data bit signals, 260, 262, . . . 264 may be coupled to the flip-flops 230, 232, . . . , 234. The (N+1) bit output control bus (CNTRL[N:0]) 250 may comprise the (N+1) stored value outputs 240, 242, . . . , 244 of the (N+1) flip-flops 230, 232, . . . , 234.

In instances when the load enable signal (LOAD) 254 is asserted, the reset (RESET) 258 may be de-asserted, and the input clock (CLOCK) 256 transitions from a de-asserted state to an asserted state, the data values for the data bit signals, 260, 262, . . . 264 may be stored in the flip-flops 230, 232, . . . 244. The values stored in the flip-flops 230, 232, . . . 244 may be output on stored value outputs 240, 242, . . . , 244. When the reset (RESET) 258 is asserted, the values stored in the flip-flops 230, 232, . . . 244 may change to determined reset values. When the load enable (LOAD) 254 is de-asserted, and the reset (RESET) 258 is de-asserted, the values stored in the flip-flops 230, 232, . . . 244 may not change as a result of transitions of the input clock (CLOCK) 256 or the data bit signals, 260, 262, . . . 264.

The flip-flops 230, 232, . . . , 234 may comprise suitable circuitry, logic, and/or code and may be adapted to load and store a plurality of control or configuration values that may be used by the control block 200 or other functional blocks in the digital frequency divider.

The control block 208 may comprise suitable circuitry, logic, and/or code and may be adapted to store a plurality of control or configuration values, that may be presented on the output control bus 250, and that may be updated using the input data bus 252 when the load signal 254 is asserted for at least one cycle of the clock 256, and the reset 256 is de-asserted.

In operation, the flip-flops 230, . . . , 234 may be reset to a determined value by asserting the reset signal 258. When the reset signal 258 is de-asserted, the flip-flops 230, . . . , 234 may store a new value from the plurality of the data inputs 260, 264 when the load signal 254 is asserted for one or more cycles of the clock 256. The plurality of the data inputs 260, . . . , 264, may comprise individual data bit values of the input data bus 252. When the reset signal 258 is de-asserted and the load signal 254 is de-asserted, the flip-flops 230, . . . , 234 may retain their stored values. The plurality of the control values 240, . . . , 244 stored by the flip-flops 230, . . . , 234 may be combined to create a plurality of output controls signals 250.

If N=2, in order to program the output control bus (CNTRL[N:0]) 250 with binary value 110, the input data bus (DATA[N:0]) 252 may be driven with binary value 110, the load enable (LOAD) 254 is asserted, and the reset (RESET) 258 is de-asserted. The data bit signal 260 may have a value of logic 0, the data bit signal 262 may have a value of logic 1, and the data bit signal 262 may have a value of logic 1. When the input clock (CLOCK) 256 transitions from a de-asserted state to an asserted state, the data values logic 0, logic 1, logic 1 on the data bit signals, 260, 262, . . . 264 may be stored in the flip-flops 230, 232, . . . 244. The values stored in the flip-flops 230, 232, . . . 244 may be output on the stored value outputs 240, 242, . . . , 244. The stored value output 240 may have a value of logic 0, the stored value output 242 may have a value of logic 1, and the stored value output 244 may have a value of logic 1.

The output control bus (CNTRL[N:0]) 250 may have a binary value of 110. When the reset (RESET) 258 is asserted, the values stored in the flip-flops 230, 232, . . . 244 may change to determined reset values. When the load enable (LOAD) 254 is de-asserted, and the reset (RESET) 258 is de-asserted, the values stored in the flip-flops 230, 232, . . . 244 may not change as a result of transitions of the input clock (CLOCK) 256 or the data bit signals, 260, 262, . . . 264.

FIG. 3 is a block diagram of an exemplary single counter 202 of FIG. 2A, which may be utilized in accordance with an embodiment of the invention. Referring to FIG. 3, the single counter 202 may comprise N flip-flops 310, 312, . . . , 314, and N flip-flops 330, 332, . . . , 334. An input clock signal (CLK) 302 may be coupled to the flip-flop 310, and the flip-flops 330, 332, . . . , 334. A counter reset signal (CNTRST) 304 may be coupled to the flip-flops 310, 312, . . . , 314, and 330, 332, . . . , 334. The stored value outputs, 360, 362, . . . 364 of the flip-flops 320, 322, . . . 324 may be coupled to the data inputs of the flip-flops 330, 332, . . . , 334. Inverted stored value outputs 320, 322, . . . , 324 of the flip-flops 310, 312, . . . , 314 are coupled to data inputs of the flip-flops 310, 312, . . . , 314, respectively. The N-bit count value (CNT[N−1:0]) 350 may comprise the N stored value outputs 340, 342, . . . , 344 of the N flip-flops 330, 332, . . . , 334. When the counter reset (CNTRST) 304 is de-asserted, and the input clock (CLK) 302 transitions from a de-asserted state to an asserted state, the data values for the data bit signals, 360, 362, . . . 364 may be stored in the flip-flops 330, 332, . . . 344. The values stored in the flip-flops 330, 332, . . . 344 may be output on the stored value outputs 340, 342, . . . , 344. When the counter reset (CNTRST) 304 is asserted, the values stored in the flip-flops 330, 332, . . . 344 may change to determined reset values.

The plurality of N flip-flops 310, 312, . . . , 314 may comprise suitable circuitry, logic, and/or code and may be adapted to return to a determined reset value when the counter reset (CNTRST) 304 is asserted, and increment an N-bit stored count value once per cycle of the clock (CLK) 302 when the counter reset 304 is de-asserted. The plurality of N flip-flops 330, 332, . . . , 334 may comprise suitable circuitry, logic, and/or code and may be adapted to update N-bits of storage elements once per cycle of the clock (CLK) 302 with the values of the plurality of N outputs 360, 362, . . . , 364 that may comprise the N-bit count value.

The single counter 202 may comprise suitable circuitry, logic, and/or code and may be adapted to receive the clock (CLK) 302 and the counter reset (CNTRST) 304 inputs, and for each cycle of the clock (CLK) 302 where the counter reset (CNTRST) 304 is de-asserted, increment a count value presented on the counter output (CNT[N−1:0]) 350, and when the counter reset (CNTRST) 304 is asserted, present a determined reset value on the counter output (CNT[N−1:0]) 350.

In operation, the feedback 320 may connect the inverted output of the flip-flop 310 with the D input of the flip-flop 310. Therefore, for every cycle of the clock (CLK) 302, the stored value in the flip-flop 310, and thus the value of flip-flop output 360, may toggle between logic 0 and logic 1. Similarly, the feedback 322 may connect the inverted output of the flip-flop 312 with the D input of the flip-flop 312. Because the clock input of the flip-flop 312 may be coupled to the feedback 320, for every two cycles of the clock 302, the stored value in the flip-flop 312, and thus the value of the flip-flop output 362, may toggle between logic 0 and logic 1. For a plurality of N flip-flops 310, 312, . . . , 314 coupled in this fashion, the output 364 of the flip-flop 314 may toggle between logic 0 and logic 1 once every 2Λ(N−1) clock cycles. For a plurality of N flip-flops 310, 312, . . . , 314 coupled in this fashion, N flip-flop outputs 360, 362, . . . , 364 form a counter value that may increment once per clock cycle, which may count through 2ΛN values. The plurality of N flip-flops 330, 332, . . . , 334 may update the N-bits of storage elements once per cycle of the clock (CLK) 302 with the values of the plurality of N outputs 360, 362 . . . , 364 that may comprise the N-bit count value. When the counter reset (CNTRST) 304 is asserted, the values stored in the flip-flops outputs 310, 312, . . . , 314 and the flip-flops 330, 332, . . . , 334 may return to a determined reset value that does not change with each cycle of the clock (CLK) 302.

FIG. 4A is a block diagram of an exemplary digital frequency divider comparator block 204 of FIG. 2A, which may be utilized in accordance with an embodiment of the invention. Referring to FIG. 4A, the comparator block 204 may comprise XNOR gates 450, . . . , 460, NAND gates 474, . . . , 478, flip-flops 486, . . . , 490, and OR gate 406. An input clock signal (CLK) 402 may be coupled to the flip-flops 486, 488, . . . , 490. The count value bit signals, 412, 414, 416, 418, . . . , 420, 422 may be coupled to bit 0, 1, . . . , N−1 of the N bit input count value bus (CNT[N−1:0]) 410. The count value bit signals, 412, 414, 416, 418, . . . , 420, 422 may be coupled to the XNOR gates 450, 452, 454, 456, . . . , 458, 460. The control word bit signals, 432, 434, 436, 438, . . . , 440, 442 may be coupled to bit 1, 2, . . . , N of the N bit input control word bus (CNTRL[N:1]) 430.

The control word bit signals, 432, 434, 436, 438, . . . , 440, 442 may be coupled to the XNOR gates 450, 452, 454, 456, . . . , 458, 460. The bit compare outputs, 462, 464, 466, 468, . . . , 470, 472 of the XNOR gates 450, 452, 454, 456, . . . , 458, 460 may be coupled to the inputs of the NAND gates 474, 476, . . . , 478. The two-bit compare outputs 480, 482, . . . , 484 of the NAND gates 474, 476, . . . , 478 may be coupled to the flip-flops 486, 488, . . . , 490. When the input clock (CLK) 402 transitions from a de-asserted state to an asserted state, the data values on the two-bit compare outputs, 480, 482, . . . , 484 may be stored in the flip-flops 486, 488, . . . , 490. The values stored in the flip-flops 486, 488, . . . , 490 may be output on the stored two-bit compare outputs 492, 494, . . . , 496, which may be coupled to the OR gate 406. The compare result (RST) 404 may be coupled to the output of the OR gate 406.

Even though FIG. 4A illustrates the inputs of the flip-flops 486, . . . , 490 coupled to the outputs of the NAND gates 474, . . . , 478, and the output of the flip-flops 486, . . . , 490 coupled to the inputs of the OR gate 406, the invention may not be so limited. Accordingly, the pipelining of logic results within the comparator block 204 may occur after the inputs 410 and 430, between any intermediate logic stage, or before the output 404, to yield an equivalent circuit.

FIG. 4B is a block diagram of the exemplary comparator block 204 of FIG. 2A, which may be utilized in accordance with another embodiment of the invention. Referring to FIG. 4B, the bit compare outputs 462, 464, 466, 468, . . . , 470, 472 of the XNOR gates 450, 452, 454, 456, . . . , 458, 460 may be coupled to the flip-flops 486, 487, 488, . . . , 489, 490. The delayed bit-compare outputs 480, 481, 482, 483, . . . , 484, 485, may be coupled to the NAND gates 474, 476, . . . 478. The two-bit compare outputs 492, 494, . . . , 496, of the NAND gates 474, 476, . . . 478 may be coupled to the OR gate 406. The compare result (RST) 404 may be coupled to the output of the OR gate 406.

Referring to FIG. 4A, even though FIG. 4A illustrates a comparator block 204 that generates an active-low comparison result signal (RST) 404, the invention may not be so limited. For example, in another embodiment, the OR gate 404 may be replaced with a NOR gate to generate an active-high comparison result signal (RST) 404.

The XNOR gates 450, . . . , 460 may comprise suitable circuitry, logic, and/or code and may be adapted to compare each bit of an N-bit count value 410 with each bit of an N-bit control value 430, and output a plurality of compare result signals 462, . . . , 472 that are active when bit [X] of the count value (CNT) 410 are identical to bit [X+1] of the control value (CNTRL) 430, where 0≦X≦N−1.

The NAND gates 474, 476, . . . , 478 may comprise suitable circuitry, logic, and/or code and may be adapted to assert a plurality of reduced compare result signals 480, . . . , 484, where each compare success output signal is asserted only if all of a subset of the plurality of compare result signals 462, . . . , 472 is asserted. Each of the compare result signals 462, . . . , 472 may be used to determine at least one of the reduced compare result signals 480, . . . , 484. Even though FIG. 4A illustrates 2-input NAND gates 474, 476, . . . , 478, the invention may not be so limited. For example, 4-input NAND gates may be coupled to the outputs of the XNOR gates 450, 452, 454, 456, . . . , 458, 460, to yield an equivalent circuit. Because one 4-input NAND gate may replace two 2-input NAND gates, the number of flip-flops 486, 488, . . . , 490 in the equivalent circuit may be reduced by a factor of two.

The flip-flops 486, 488, . . . , 490 may comprise suitable circuitry, logic, and/or code and may be adapted to store M bits of an intermediate comparison result, updated once per cycle of the clock 402, where N≧M≧1, and N is bus width of the count value 410 and the control value 430. When the input clock (CLK) 402 transitions from a de-asserted state to an asserted state, the storage elements in the flip-flops 486, 488, . . . , 490 may be updated with the data values on the inputs 480, 482, . . . , 484. The values stored in the flip-flops 486, 488, . . . , 490 may be output on the flip-flop outputs 492, 494, . . . , 496.

The OR gate 406 may comprise suitable circuitry, logic, and/or code and may be adapted to assert a comparison result signal 404 when all of the compare inputs 408 are asserted, and to otherwise de-assert the comparison result signal 404.

The comparator block 204 may comprise suitable circuitry, logic, and/or code and may be adapted to compare an N-bit count value 410 with an N-bit control value 430, and assert an output comparison result signal (RST) 404, that may be delayed by one or more cycles of the clock 402, when the N-bit count value 410 and the N-bit control value 430 are identical. Even though FIG. 4A illustrates a comparator block 204 that generates an active-low comparison result signal (RST) 404, the invention may not be so limited. For example, in another embodiment, a NOR gate may be substituted in place of the OR gate 406 to generate an active-high comparison result signal (RST) 404.

In operation, a plurality of N two-input XNOR gates 450, . . . , 460 may compare bit M of the N-bit count value (CNT) 410, with bit M+1 of the N-bit control value (CNTRL) 430, where N>M≧0, to generate a plurality compare result signals 462, . . . , 472. Pairs of the plurality of result signals 462, . . . , 472 may be coupled to the inputs of N/2 two-input NAND gates 474, . . . , 478, to generate a plurality of N/2 reduced compare result signals 480, . . . , 484. The plurality of N/2 reduced compare result signals 480, . . . , 484 may be registered by a plurality of N/2 flip-flops 486, . . . , 490, to generate a plurality of registered reduced compare result signals 492, . . . , 496. The plurality of registered reduced compare result signals 492, . . . , 496 may be coupled to the plurality of inputs of the OR gate 406, to generate a comparison result signal 404, which is asserted when the N-bit count value 410 and the N-bit control value 430 are identical. A new comparison operation begins when there is a change in the N-bit count values (CNT) 410 or the N-bit control value (CNTRL) 430. The comparison result signal (RST) 404 may be updated once per cycle of the clock (CLK) 402.

For example, in operation, if N=8, and the count value (CNT[N−1:0]) is binary value 01101010, and the control word (CNTRL[N:1]) is binary value 01101010, the eight bit compare outputs, 462, 464, 466, 468, . . . , 470, 472 of the eight XNOR gates 450, 452, 454, 456, . . . , 458, 460 are binary 11111111. The eight bit compare outputs, 462, 464, 466, 468, . . . , 470, 472 are input to the four NAND gates 474, 476, . . . , 478, and four two-bit compare outputs 480, 482, . . . , 484 of the NAND gates 474, 476, . . . , 478 are binary value 0000. When the input clock (CLK) 402 transitions from a de-asserted state to an asserted state, the storage elements in the four flip-flops 486, 488, . . . , 490 may be updated with the binary 0000 data values on the inputs, 480, 482, . . . , 484. The flip-flop outputs 492, 494, . . . , 496 with binary value of 0000 are inputs to the OR gate 406, and the OR gate 406 may assert an active-low comparison result output (RST) 404.

For example, in operation, if N=8, and the count value (CNT[N−1:0]) is binary value 00000000, and the control word (CNTRL[N:1]) is binary value 01000000, the eight bit compare outputs, 462, 464, 466, 468, . . . , 470, 472 of the eight XNOR gates 450, 452, 454, 456, . . . , 458, 460 are binary 01111111. The eight bit compare outputs, 462, 464, 466, 468, . . . , 470, 472 are input to the NAND gates 474, 476, . . . , 478, and two-bit compare outputs 480, 482, . . . , 484 of the NAND gates 474, 476, . . . , 478 are binary value 1000. When the input clock (CLK) 402 transitions from a de-asserted state to an asserted state, the storage elements in the flip-flops 486, 488, . . . , 490 may be updated with the binary 1000 data values on the inputs, 480, 482, . . . , 484. The flip-flop outputs 492, 494, . . . , 496 with binary value of 1000 are inputs to the OR gate 406, and the OR gate 406 may de-assert an active-low comparison result output (RST) 404.

FIG. 5 is a block diagram of the exemplary counter reset and output generation block 206 of FIG. 2A, which may be utilized in accordance with an embodiment of the invention. Referring to FIG. 5, the counter reset and output generation block 206 may comprise multiplexer 520, latch 514, AND gates 516 and 518, and flip-flops 510, 512, and 522. An input clock signal (CLK) 504 may be coupled to the flip-flops 510 and 512, and the latch 514. An input control bit signal (CTRL[0]) 506 may be coupled to the AND gate 518.

An input reset signal (RST) 502 may be coupled to the AND gate 516, and the flip-flops 510 and 512. The delayed reset 532 output of the flip-flop 512 may be coupled to the multiplexer 520. The delayed reset 530 output of the flip-flop 510 may be coupled to the AND gate 516. The counter reset output (CNTRST) 542 of the AND gate 516 may be coupled to the latch 514, and may be an output of the counter reset and output generation block 206. The pre-multiplexed clock 536 output from the latch 514 may be coupled to the multiplexer 520. The multiplexed clock 534 output from the multiplexer 520 may be coupled to the flip-flop 522. The inverting output 538 of the flip-flop 522 may be coupled to the data input of the flip-flop 522.

The counter reset output (CNTRST) 542 of the AND gate 516 may be coupled to the latch 514, and may be an output of the counter reset and output generation block 206. The frequency divided output (DIVOUT) 544 of the flip-flop 522 may be coupled to the AND gate 518, and may be an output of the counter reset and output generation block 206. The odd division falling edge select 540 output of the AND gate 518 may be coupled to the multiplexer 520 and the flip-flop 510.

Even though FIG. 5 illustrates a circuit that accepts an active-low reset input (RST) 502, the invention may not be so limited. For example, the reset input (RST) 502 may be coupled to the input of an additional inverter, and the inverter output may be coupled to the D inputs of the flip-flops 512 and 510, and to the input of the AND gate 516, to create a circuit that accepts an active-high reset input (RST) 502.

Even though FIG. 5 illustrates a circuit that may generate an active-low counter reset output (CNTRST) 542, the invention may not be so limited. For example, the AND gate 516 may be replaced with a NAND gate, and the latch 514 may be replaced with a latch with an inverting output, to create a circuit that may generate an active-high counter reset output (CNTRST) 542.

The flip-flop 512 may comprise suitable circuitry, logic, and/or code and may be adapted to store a single-bit logic value, updated once per cycle of the clock (CLK) 504 with the logic value of reset (RST) 502. The logic value of the storage element in the flip-flop 512 may be output on the delayed reset 532.

The flip-flop 510 may comprise suitable circuitry, logic, and/or code and may be adapted to store a single-bit logic value, updated once per cycle of the clock (CLK) 504 with the logic value of the reset (RST) 502 when the odd division falling edge select 540 is de-asserted. The logic value of the storage element in the flip-flop 510 may be set when the odd division falling edge select 540 is asserted. The logic value of the storage element in the flip-flop 510 may be output on the delayed reset 530.

The flip-flop 522 may comprise suitable circuitry, logic, and/or code and may be adapted to store a single-bit logic value, updated once per cycle of the multiplexed clock 534 with the inverted frequency divided output 538. The logic value of the storage element in the flip-flop 522 may be reflected on the output coupled to the frequency divided output (DIVOUT) 544. The inverse of the logic value of the storage element in the flip-flop 522 may be output on the inverted frequency divided output 538.

The latch 514 may comprise suitable circuitry, logic, and/or code and may be adapted to pass through the value of the counter reset (CNTRST) 542 to the pre-multiplexed clock 536 when the clock (CLK) 504 is de-asserted, and capture a value of the counter reset (CNTRST) 542 when the clock (CLK) 504 transitions from a de-asserted state to an asserted state. The latch 514 may comprise suitable circuitry, logic, and/or code and may be adapted to drive the said captured value of the counter reset (CNTRST) 542 to the pre-multiplexed clock 536 when the clock (CLK) 504 is asserted.

The AND gate 516 may comprise suitable circuitry, logic, and/or code and may be adapted to perform a logic AND of the reset (RST) 502 and the delayed reset 530. The result of the logic AND operation may be driven onto the counter reset (CNTRST) 542.

The AND gate 518 may comprise suitable circuitry, logic, and/or code and may be adapted to perform a logic AND of the control bit (CTRL[0]) 506 and the frequency divided output (DIVOUT) 544. The result of the logic AND operation may be driven onto the odd division falling edge select 540.

The multiplexer 520 may comprise suitable circuitry, logic, and/or code and may be adapted to pass through the delayed reset 532 to the multiplexed clock 534 when the odd division falling edge select 540 is de-asserted. The multiplexer 520 may comprise suitable circuitry, logic, and/or code and may be adapted to pass through the pre-multiplexed clock 536 to the multiplexed clock 534 when the odd division falling edge select 540 is asserted.

The counter reset and output generation block 206 may comprise suitable circuitry, logic, and/or code and may be adapted to generate the frequency divided output (DIVOUT) 544 and the counter reset signal (CNTRST) 542 using the reset (RST) 502, the clock (CLK) 504, and the control bit (CTRL[0]) 506. When the control bit (CTRL[0]) 506 is de-asserted, the frequency divided output (DIVOUT) 544 is an even frequency division of clock (CLK) 504, and the multiplexer 520 may select the delayed reset 532 as the clock input to toggle the frequency divided output (DIVOUT) 544 of the flip-flop 522. When the control bit (CTRL[0]) 506 is asserted the frequency divided output (DIVOUT) 544 is an odd frequency division of the clock (CLK) 504. When the frequency divided output (DIVOUT) signal 544 (DIVOUT) 544 is de-asserted, the multiplexer 520 may select the delayed reset 532 as the clock input to toggle the frequency divided output (DIVOUT) 544 of the flip-flop 522 from a de-asserted state to an asserted state. When the frequency divided output (DIVOUT) signal 544 is asserted, the multiplexer 520 may select the pre-multiplexed clock 536 as the clock input to toggle the frequency divided output (DIVOUT) 544 of the flip-flop 522 from an asserted state to a de-asserted state.

When the control bit (CTRL[0]) 506 is de-asserted, the frequency divided output (DIVOUT) 544 is an even frequency division of the clock (CLK) 504, the SET input of flip-flop 510 is asserted, and therefore the delayed reset 530 is asserted. The counter reset signal (CNTRST) 542 may be generated using a logic AND result of the asserted delayed reset signal 530 and the reset signal (RST) 502. Therefore reset signal (CNTRST) 542 is the reset signal (RST) 502 with a propagation delay introduced by the AND gate 516. When the control bit (CTRL[0]) 506 is asserted, and the frequency divided output (DIVOUT) 544 is de-asserted, the frequency divided output (DIVOUT) 544 is an odd frequency division of the clock (CLK) 504, the SET input of flip-flop 510 is asserted, and therefore the delayed reset signal 530 is asserted. The counter reset signal (CNTRST) 542 may be generated using a logic AND result of the asserted delayed reset signal 530 and the reset signal (RST) 502. Therefore reset signal (CNTRST) 542 is the reset signal (RST) 502 with a propagation delay introduced by the AND gate 516.

When the control bit (CTRL[0]) 506 is asserted and the frequency divided output (DIVOUT) 544 is asserted, the frequency divided output (DIVOUT) 544 is an odd frequency division of the clock (CLK) 504, the delayed reset 530 may be (RST) 502 with one clock cycle delay of (CLK) 504, and therefore, the assertion of the counter reset signal (CNTRST) 542 occurs on the same clock cycle as the assertion of the reset (RST) 502 and the de-assertion of counter reset signal (CNTRST) 542 occurs on the clock cycle following the de-assertion of rest (RST) 502. Therefore, for odd frequency division, after M clock cycles, the counter reset signal (CNTRST) 542 may alternate between assertions of 1 clock cycle and 2 clock cycles in duration, where M is the value of bits [N:1] of the control word (CTRL[N:1]) 222 of control block 208.

In operation, referring to FIG. 5 and FIG. 2A, the reset input (RST) 502 is asserted when the comparator block 204 detects that the count value (CNT[N−1:0]) 212 of the single counter 202 reaches the value specified in bits [N:1] of the control word (CTRL[N:1]) 222 of the control block 208. The flip-flop 512 may be used to generate a delayed reset 532 from the reset input (RST) 502. When the control bit (CTRL[0]) 506 and the frequency divided output (DIVOUT) 544 are asserted, the frequency divided output (DIVOUT) 544 is an odd frequency division of the clock (CLK) 504 The odd division falling edge select 540, the flip-flop 510, the AND gate 516, and the latch 514 may be used to generate a pre-multiplexer clock 536 whose de-asserted state to asserted state transition is 180 degrees out of phase with the de-asserted state to asserted state transition of the delayed reset 532.

When the control bit (CTRL[0]) 506 is de-asserted, the frequency divided output (DIVOUT) 544 is an even frequency division of the clock (CLK) 504, and the delayed reset 532 may be used as the clock input to toggle the frequency divided output (DIVOUT) 544 of the flip-flop 522 between a de-asserted state and an asserted state.

When the control bit (CTRL[0]) 506 is asserted and the frequency divided output (DIVOUT) 544 is de-asserted, the frequency divided output (DIVOUT) 544 is an odd frequency division of the clock (CLK) 504. The delayed reset 532 may be used as the clock input to toggle the frequency divided output (DIVOUT) 544 of the flip-flop 522 from a de-asserted state to an asserted state. When the control bit (CTRL[0]) 506 is asserted and the frequency divided output (DIVOUT) 544 is asserted, the frequency divided output (DIVOUT) 544 is an odd frequency division of the clock (CLK) 504. The pre-multiplexed clock 536 may be used as the clock input to toggle the frequency divided output (DIVOUT) 544 of the flip-flop 522 from an asserted to a de-asserted state, which may allow for an approximately 50% duty cycle of frequency divided output (DIVOUT) 544 when odd frequency division of the clock (CLK) 504 is selected.

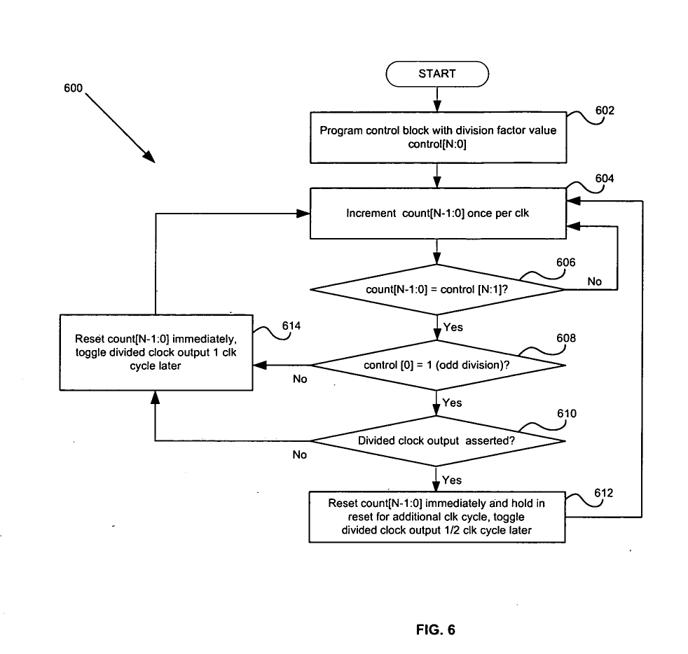

FIG. 6 is a flow diagram of exemplary steps for digitally generating frequency divided output signals, in accordance with an embodiment of the invention. Referring to FIG. 6, at step 602, bits N:0 of a (N+1) bit control word, control[N:0] may be configured with the frequency factor the input clock will be divided by to yield the output clock. At step 604, the counter block count value, count[N−1:0], may be incremented once per clock cycle. At step 606, the comparator block may compare count[N−1:0] with control[N:1]. If the comparison fails because count[N−1:0] and control[N:1] are not equal, control passes back to step 604, where the counter block count value may be incremented again. The comparison between count[N−1:0] with control[N:1] may be repeated, until the comparison succeeds, at which time control passes to step 608.

At step 608, control block control[0] may be evaluated to determine whether the frequency division factor is odd or even. If control[0] is de-asserted, then the frequency division factor is even, and control passes to step 614. At step 614, the counter may be reset immediately and the divided clock output may be toggled one clock cycle later. Control then passes back to step 604, where the counter block count value is incremented.

In step 608, if control[0] is asserted, then the frequency division factor is odd, and at 610, the divided clock output is checked to determine whether the divided clock output is asserted. In step 610, if the divided clock output is not asserted, control passes to step 614, where the counter may be reset immediately, and the divided clock output may be toggled one clock cycle later. In step 610, if the divided clock output is asserted, control passes to step 612. At step 612, counter may be reset immediately and may be held in a reset state for an additional clock cycle, for total of two clock cycles, and the divided clock output may be toggled one-half clock cycle later, and control passes to step 604.

Referring to FIG. 2A, a count value may be generated based on a number of cycles of the input signal (CLK) 210. The generated count value (CNT[N−1:0]) 212 may be compared with the factor value (CNTRL[N:1]) 222 to generate a match signal (RST) 214 comprising a pipelined match signal. The comparison may be performed utilizing a pipelined count value (CNT[N−1:0]) 212. An output signal resulting from the digital frequency dividing (DIVOUT) 216 may be toggled utilizing the match signal (RST) 214. The digital frequency dividing may be performed utilizing a single comparator block 204 and may be performed utilizing a single counter 202. Referring to FIG. 5 one of two clock signals 532 and 536 may be selected and utilized to toggle the output signal (DIVOUT) 522. One bit of the factor value (CNTRL[0]) 506, and the output signal (DIVOUT) 522, may be utilized to select one of two clock signals 532 and 536.

Accordingly, aspects of the invention may be realized in hardware, software, firmware or a combination thereof. The invention may be realized in a centralized fashion in at least one computer system or in a distributed fashion where different elements are spread across several interconnected computer systems. Any kind of computer system or other apparatus adapted for carrying out the methods described herein is suited. A typical combination of hardware, software and firmware may be a general-purpose computer system with a computer program that, when being loaded and executed, controls the computer system such that it carries out the methods described herein.

One embodiment of the present invention may be implemented as a board level product, as a single chip, application specific integrated circuit (ASIC), or with varying levels integrated on a single chip with other portions of the system as separate components. The degree of integration of the system will primarily be determined by speed and cost considerations. Because of the sophisticated nature of modern processors, it is possible to utilize a commercially available processor, which may be implemented external to an ASIC implementation of the present system. Alternatively, if the processor is available as an ASIC core or logic block, then the commercially available processor may be implemented as part of an ASIC device with various functions implemented as firmware.

The present invention may also be embedded in a computer program product, which comprises all the features enabling the implementation of the methods described herein, and which when loaded in a computer system is able to carry out these methods. Computer program in the present context may mean, for example, any expression, in any language, code or notation, of a set of instructions intended to cause a system having an information processing capability to perform a particular function either directly or after either or both of the following: a) conversion to another language, code or notation; b) reproduction in a different material form. However, other meanings of computer program within the understanding of those skilled in the art are also contemplated by the present invention.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A method for generating a signal, the method comprising digitally frequency dividing a input signal by a factor value specified as an N+1-bit value, utilizing a counter of N bits.

2. The method according to claim 1, further comprising generating a count value based on a number of cycles of said input signal.

3. The method according to claim 2, further comprising comparing said generated count value with said factor value to generate a match signal.

4. The method according to claim 3, further comprising toggling an output signal from said digitally frequency dividing utilizing said match signal.

5. The method according to claim 3, further comprising performing said comparing utilizing a pipelined count value.

6. The method according to claim 3, wherein said match signal comprises a pipelined match signal.

7. The method according to claim 1, further comprising performing said digital frequency dividing utilizing a single comparator.

8. The method according to claim 1, further comprising performing said digital frequency dividing utilizing a single counter.

9. The method according to claim 1, further comprising toggling an output signal from said digitally frequency dividing utilizing two clock signals.

10. The method according to claim 9, further comprising selecting one of said two clock signals to toggle said output signal utilizing one bit of said factor value.

11. The method according to claim 9, further comprising selecting one of said two clock signals to toggle said output signal utilizing said output signal.

12. The method according to claim 9, wherein said two clock signals are 180 degrees out of phase with respect to each other.

13. A system for generating a signal, the system comprising a digital frequency divider that divides an input signal by a factor value specified as an N+1-bit value, utilizing a counter of N bits.

14. The system according to claim 13, further comprising circuitry that generates a count value based on a number of cycles of said input signal.

15. The system according to claim 14, further comprising circuitry that compares said generated count value with said factor value to generate a match signal.

16. The system according to claim 15, further comprising circuitry that toggles an output signal from said digitally frequency divider utilizing said match signal.

17. The system according to claim 15, further comprising circuitry that performs said comparing utilizing a pipelined count value.

18. The system according to claim 15, wherein said match signal comprises a pipelined match signal.

19. The system according to claim 13, further comprising circuitry that performs said digital frequency dividing utilizing a single comparator.

20. The system according to claim 13, further comprising circuitry that performs said digital frequency dividing utilizing a single counter.

21. The system according to claim 13, further comprising circuitry that toggles an output signal from said digitally frequency divider utilizing two clock signals.

22. The system according to claim 21, further comprising circuitry that selects one of said two clock signals to toggle said output signal utilizing one bit of said factor value.

23. The system according to claim 21, further comprising circuitry that selects one of said two clock signals to toggle said output signal utilizing said output signal.

24. The system according to claim 21, wherein said two clock signals are 180 degrees out of phase with respect to each other.

25. A system for generating a signal, the system comprising:
a digital frequency divider comprising:
a N-bit counter coupled to an input clock signal;
a N-bit comparator coupled to an output of said N-bit counter and input clock signal;
a reset and output generator coupled to an output of said N-bit comparator and said input clock signal, wherein an output of said reset and output generator is coupled to an input of said N-bit counter; and
a controller coupled to an input of said N-bit comparator and an input of said reset and output generator, wherein an output of said digital frequency divider is an output of said reset and output generator.

26. The system according to claim 25, wherein said reset and output generator comprises:
a first flip-flop;
a MUX coupled to an output of said first flip-flop, wherein said an output of said first flip-flop is coupled to a first input of said MUX;
a latch coupled to a second input of said MUX, wherein:
an output of a first AND gate is coupled to an first input of said latch, and is said output of said reset and output generator that is coupled to said input of said N-bit counter; and
a first input of said first AND gate is coupled to an output of a second flip-flop;
a second AND gate, wherein an output of said second AND gate is coupled to an input of said second flip-flop and a select of said MUX;
a third flip-flop, wherein:
a first input of said third flip-flop is coupled to an output of said MUX;
a first output of said third flip-flop is said output of said digital frequency divider that is said output of said reset and output generator, and is coupled to a first input of said second AND gate;
a second output of said third flip-flop is coupled to a second input of said third flip-flop; and
a second input of said second AND gate is coupled to at least a portion of an output of said controller;
wherein:
said input clock signal is coupled to an input of said first flip-flop, and input of said second flip-flop, and input of said latch; and
said output of said N-bit comparator is coupled to an input of said first flip-flop, and input of said second flip-flop, and a second input of said AND gate.

27. The system according to claim 25, wherein said N-bit counter is reset once per toggle of said output of said digital frequency divider.
